(19) United States
(12) Patent Application Publication
(10) Pub. No.: US 2019/0045657 A1
(43) Pub. Date: Feb. 7, 2019

(54) RESILIENT CONTACT TERMINAL

(71) Applicant: JOINSET CO., LTD., Ansan-si (KR)

(72) Inventors: Sun-Ki Kim, Gunpo-si (KR); Tae-Man Kang, Ansan-si (KR)

(73) Assignee: JOINSET CO., LTD.

(21) Appl. No.: 16/157,316

(22) Filed: Oct. 11, 2018

Related U.S. Application Data
(63) Continuation of application No. PCT/KR2018/000236, filed on Jan. 5, 2018.

(30) Foreign Application Priority Data
Jan. 6, 2017 (KR) 10-2017-0002623
Jan. 18, 2017 (KR) 10-2017-0008540
Apr. 14, 2017 (KR) 10-2017-0048282

(51) Int. Cl. H05K 7/20; H01R 13/24; H01R 12/55; H05K 1/02; H05K 9/00; H01H 1/24; F28F 3/00

(52) U.S. Cl. CPC H05K 7/2039; H01R 13/2407; H01R 12/55; H01L 23/367; H05K 9/0026; H01H 1/24; F28F 3/00; H05K 1/0203

(57) ABSTRACT

A resilient contact terminal having a structure that can be applied to various purposes. The contact terminal has: a base; a plurality of bridges of which one end is connected to the base, is spirally wound and extends in upward inclination, and which thus are vertically resilient; and a contact portion connected to the other end of each bridge. A gap portion separates the bridges and the contact portion, and the bridges and the base. The edge of the base is positioned further outward than the edge of the contact portion.

### REFERENCE TO RELATED APPLICATIONS

This is a continuation of International Patent Application PCT/KR2018/000236 filed on Jan. 5, 2018, which designates the United States and claims priority of Korean Patent Application No. 10-2017-0002623 filed on Jan. 6, 2017, and Korean Patent Application No. 10-2017-0008540 filed on Jan. 18, 2017, and Korean Patent Application No. 10-2017-0048282 filed on Apr. 14, 2017, the entire contents of which are incorporated herein by reference.

### FIELD OF THE INVENTION

The present invention relates to an elastic contact terminal, and more particularly, to an elastic contact terminal having a structure applied for a variety of purposes.

### BACKGROUND OF THE INVENTION

Korean Patent Registration No. 1644119, filed by the present applicant, discloses an elastic electrical contact terminal including: a plate-shaped fixing part of which the lower surface can be reflow-soldered on a circuit substrate by using solder cream; a plate-shaped contact part spaced apart upwards from the fixing part, having, on the upper surface thereof, a portion which can be at least vacuum-picked up and having a size smaller than that of the fixing part; and an elastic spring part including a plurality of bridges of which one end is erected upwards and bent from an edge of the fixing part and extends by being wound along the edge, wherein one end of each bridge is positioned so as to face one end of another bridge, the other end of any one of the bridges is connected to the contact part, the other end of another bridge is positioned at the lower surface of the contact part, and the fixing part, the contact part and the spring part are formed of a metal and are integrally formed by press molding.

According to the above components, since the contact part is supported by a pair of bridges wound at a certain interval, a structure is complicated and the bridges have a width parallel to a height direction much greater than a thickness, a height increases.

Also, Korean Patent Registration No. 1626030 discloses an elastic electrical contact terminal including a plate-shaped contact portion; a plate-shaped fixing part; a first spring part wound downward in a first direction with a diameter being reduced; a second spring part wound downward in a second direction opposite to the first direction with a diameter being increased; and a support part which has one end connected to the first spring part and the second spring part to be surrounded by the first spring part and the second spring part and is rolled in the first direction to allow the other end to be open.

According to the components, since the first and second spring parts are wound in opposite directions, a structure is completed and it is difficult to manufacture the structure. Also, since being wound in opposite directions while the bridges have a width parallel to a height direction much greater than a thickness, a height increases.

Korean Patent Publication No. 2016-72758 discloses an electrical contact terminal including an elastic contact portion which is formed of a conductive material, is formed to be convex upward, and includes a plurality of spiral incised grooves, on a convex surface, spirally extending outward from a center in a radial direction such that a central part thereof is pressurized downward by an external force; and a fixing portion which extends from one side or both sides of the elastic contact portion an is attached to a target surface.

According to the components, since the elastic contact portion is not separated from the fixing part, a more pressurizing force is necessary and an area in contact with an object is small.

Meanwhile, the above electrical contact terminal is elastically interposed between one object and another object to be used as an electrical path between top and bottom and is not applicable to, for example, a switch or a thermally conductive member.

Also, it is difficult to provide an economic electrical contact terminal having a low height, a long operational distance, reliable elasticity, and a reliable restoring force.

### SUMMARY OF THE INVENTION

The present invention is directed to providing an elastic contact terminal capable of being used for a variety of purposes.

The present invention is also directed to providing an elastic contact terminal capable of being used for heat conductivity and electrical conductivity.

The present invention is also directed to providing an elastic contact terminal which has a low height, a long operational distance, reliable elasticity, and a reliable restoring force.

The present invention is also directed to providing an elastic contact terminal with a less force of being pressurized by an object.

One aspect of the present invention provides an elastic contact terminal, which is formed of a single body having a metal material, the elastic contact terminal including a base, a plurality of bridges which have one end connected to the base, are spirally wound, extend in an upward inclination, and have vertical elasticity, and a contact portion to which the other end of each of the bridges is connected. Here, each of the bridges extends between the contact portion and the base while maintaining a certain interval therebetween, and the bridges have a horizontal width greater than a vertical thickness.

Edges of the base may be bent upward or downward and form ribs, and an accommodation portion may be formed inside the ribs, which are bent downward, such that a thermally conductive member may be accommodated in the accommodation portion.

A reinforcing portion, which extends toward a perpendicular line with respect to the winding direction, may be formed a part of the bridge which is connected to the base and the contact portion, and the certain interval may be maintained throughout the bridge due to the reinforcing portion.

A thermally conductive member may be installed on a top surface or a bottom surface of the contact portion or a bottom surface of the base.

The thermally conductive member may include any one of thermally conductive rubber, thermally conductive metal, thermally conductive ceramic, and thermally conductive carbon.

The thermally conductive member installed on the bottom surface of the contact portion may be formed by stacking a large-sized first thermally conductive member and a small-sized second thermally conductive member, and the first thermally conductive member may cover a space formed in the base by the bridges and the second thermally conductive member may cover a space formed by the contact portion so as to fill an empty space formed inside the base.

Edges of the base may be bent upward and form ribs, and a thickness of a thinnest part of the thermally conductive member installed on the other side of the contact portion may be greater than a height of the ribs.

The thermally conductive member may have elasticity and self adhesion.

One or more embossings may protrude upward from a top surface of the contact portion or protrude downward from a bottom surface of the contact portion.

An embossing may protrude downward from a bottom surface of the contact portion and operate as an electrical contact point when the contact portion is pressurized downward.

An embossing may protrude downward from a bottom surface of the contact portion. Here, the base may be electrically connected to a first conductive pattern, and the embossing may be, selectively, electrically connected to a second conductive pattern by vertical movement of the contact portion and perform switching between the first and second conductive patterns.

An embossing or a beading may protrude upward from a top surface of the base corresponding to each corner thereof.

The contact terminal may include a plating layer formed at an outermost part thereof by consecutively plating nickel and gold or plating tin or silver so as to have high environmental resistance and to be reflow-soldered using a solder cream.

A carbon layer having high heat conductivity may be formed on an outer surface of the contact terminal. Here, the carbon layer may be formed by adhering, coating, or vapor-deposing carbon fibers, graphite, or graphene.

According to the above configuration, the same structure may be used as an electrical contact terminal, a thermally conductive terminal, and an electrical switch so as to be used for a variety of purposes.

When the contact terminal is used as an electrical contact terminal, electrical resistance and an inductance value are decreased through combination with an electroconductive elastic member.

When the contact terminal is used as a thermally conductive terminal, a material thereof may be formed of a metal having excellent heat conductivity so as to adequately perform heat transfer and heat diffusion and may be easily installed between objects, to which heat is to be transferred, and come into elastic contact with each of the objects so as to reduce heat resistance.

Also, since a contact portion is supported by only bridges which independently extend from a base, a less pressurizing force is necessary. Since the bridges have a horizontal width greater than a vertical thickness, the bridges may have a low height and a long operational distance and may provide reliable elasticity and a restoring force.

Also, an embossing protrudes from a top surface or a bottom surface of the contact portion so as to undoubtedly perform electrical contact when the contact terminal is used as a contact terminal or a switch.

Also, a thermally conductive member is applied to the bottom surface of the contact portion so as to adequately perform heat transfer and heat diffusion and to provide elasticity and a restoring force. However, when the thermally conductive member is not present, an operational distance is long.

Also, since the bridges have a horizontal width greater than a vertical thickness, the bridges may have a low height and a long operational distance and may provide reliable elasticity and a reliable restoring force.

Also, since the operational distance, in which the contact portion is pressurized, is restricted by ribs, beadings, or embossings which protrude from the top surface of the base so as to provide reliable elasticity and a reliable restoring force and to increase mechanical strength of the base which reduces distortion overall, reflow-soldering may be easily performed and intensity of soldering may be improved.

### BRIEF DESCRIPTION OF THE DRAWINGS

FIGS. 1A, 1B, and 1C are a perspective view, a side view, and a plane view of an elastic contact terminal according to one embodiment of the present invention.

FIG. 2 is a perspective view of an elastic contact terminal according to another embodiment of the present invention.

FIGS. 3A and 3B are perspective views of elastic contact terminals according to other embodiments of the present invention.

FIGS. 4A and 4B are perspective views of the elastic contact terminal according to another embodiment of the present invention.

FIGS. 5A and 5B are perspective views of an elastic contact terminal according to another embodiment of the present invention.

FIG. 6 is a perspective view of an elastic contact terminal according to another embodiment of the present invention.

FIG. 7 is a perspective view of an elastic contact terminal according to another embodiment of the present invention.

### DETAILED DESCRIPTION OF THE INVENTION

It should be noted that the technical terms used herein are merely for explaining particular embodiments and are not intended to limit the present invention. Also, the technical terms used herein, unless defined otherwise, should be interpreted as having meanings generally understood by one of ordinary skill in the art and not be interpreted as having excessively comprehensive meanings or excessively reduced meanings. Also, when the technical terms used herein are wrong technical terms which can not clearly represent the concept of the present invention, they should be understood while being replaced by technical terms capable of being properly understood by those skilled in the art. Also, general terms used herein should be interpreted according to the defined in a dictionary or according to back-and-forth context and not be understood as having excessively reduced meanings.

Hereinafter, exemplary embodiments of the present invention will be described in detail with reference to the attached drawings.

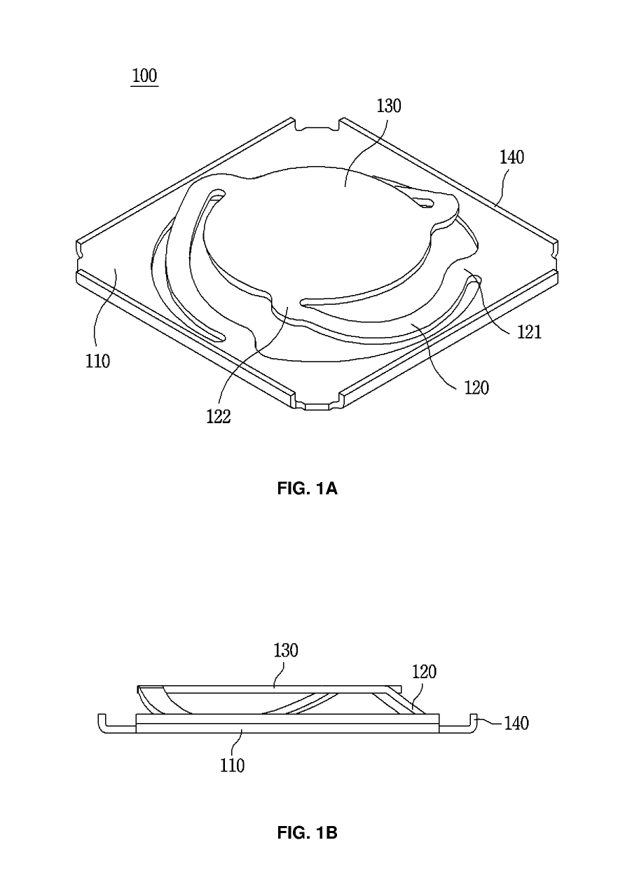

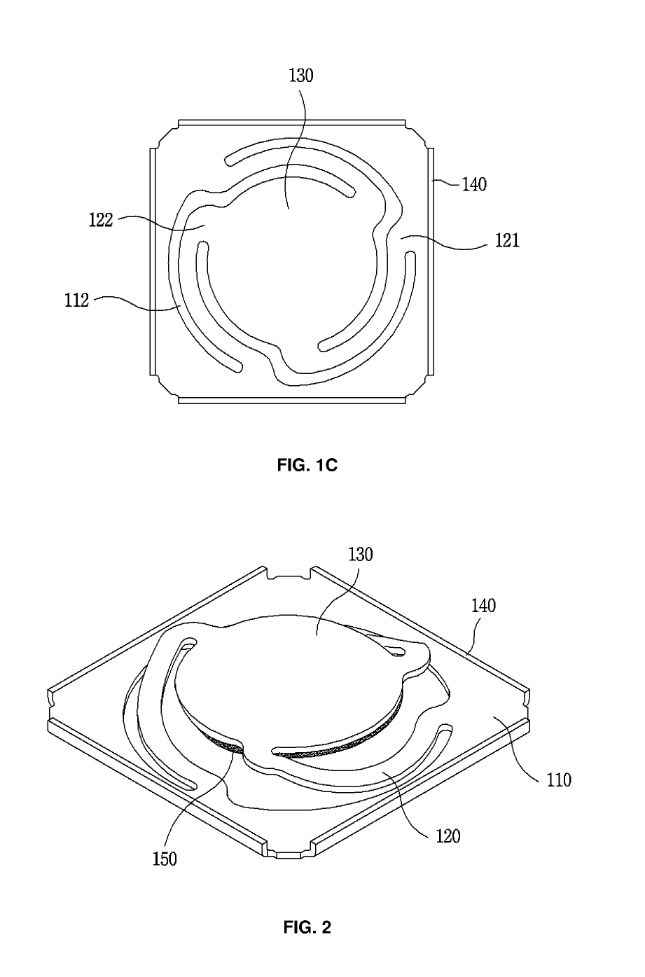

FIGS. 1A, 1B, and 1C are a perspective view, a side view, and a plane view of an elastic contact terminal according to one embodiment of the present invention.

An elastic contact terminal 100 may be interposed between objects, which face each other, to be used for forming an electrical path or a heat path between the objects.

Here, the objects may be electroconductive objects such as a metal case and a conductive pattern on a circuit board or thermally conductive objects such as a metal case and a heating element.

Accordingly, the contact terminal 100 is formed of an electroconductive metal or thermally conductive metal, for example, a metal having high strength such as a copper alloy and stainless steel and is integrally formed as a single body.

The contact terminal 100 is consecutively manufactured by supplying a high-strength metal sheet having a certain thickness as a roll and blanking and bending the metal sheet by a press mold. The thickness of the high-strength metal sheet may be, for example, 0.05 mm to 0.3 mm.

When necessary, in the contact terminal 100, a plating layer may be formed by consecutively plating nickel and gold or plating tin or silver on an outermost part such that environment resistance may be high and it is possible to perform reflow soldering using a solder cream.

The contact terminal 100 includes a base 110, a plurality of bridges 120 which are spirally wound and extend from the base 110 and have vertical elasticity, and a contact portion 130 to which ends of the bridges 120 are connected.

Here, although the base 110 and the contact portion 130 are differently designated merely for convenience of description, both the base 110 and contact portion 130 include a function of being in contact with an object.

A size of the contact terminal 100 is not particularly limited but may be, for example, within a range of 1.5 to 10 mm wide, 1.5 to 10 mm long, and 0.5 to 3 mm high.

The contact terminal 100 may be supplied to a reel tape carrier and vacuum-picked-up by the contact portion 130 and a bottom surface of the base 110 may be mounted on the object by reflow-soldering using a solder cream but they are not limited thereto and may adhere thereto using adhesive tapes or may be mechanically combined.

The contact terminal 100 may be directly fixed to the object by the above-described soldering or welding or may be fixed interposing a metal pad interface.

As described above, the bridges 120, the contact portion 130, and interval portions 112, which space the bridges 120 and the base 110 apart, may be formed by blanking using a press mold as shown in FIG. 10.

Accordingly, the bridges 120 extend to connect the base 110 to the contact portion 130 while maintaining certain intervals formed between the base 110 and the contact portion 130 by the interval portions 112.

Afterwards, boundary parts between the bridges 120 and the base 110, that is, one ends of the bridges 120 are bent upward such that other ends of the bridges 120 and the contact portion 130 have moved upward to a uniform height to protrude.

Since the contact portion 130 is formed by blanking using a press mold, the contact portion 130 is always formed inside the base 110 and edges of the base 110 are located outside edges of the contact portion 130 as a result.

Also, since parts except the bridges 120 and the interval portions 112 having certain widths form the contact portion 130 such that a contact area with the object significantly increases and the contact portion 130 is supported by the other ends of the bridges 120, elasticity and restorability are high and a pressure is low.

In the embodiment, the base 110 has a quadrangular shape and the contact portion 130 has a circular shape but they are not limited thereto.

Optionally, the edges of the base 110 are bent upward and form ribs 140 so as to function as stoppers. In other words, when the contact portion 130 is pressurized by the object, the contact portion 130 moves downward. Here, the object is held by the ribs 140 such that the contact portion 130 does not further move downward.

Also, since mechanical strength of the base 110 is increased by the ribs 140 such that the base 110 is not easily distorted or bent to be mechanically stable and a bottom surface of the contact terminal 100 forms a plane to be easily surface-mounted.

When it is intended to increase only the mechanical strength of the base 110, the edges of the base 110 may be bent downward to form the ribs 140.

The edges of the contact portion 130 are formed to be inclined downward so as to prevent the contact portion 130 from being held by an external obstacle and being bent.

As described above, the bridges 120 are integrally formed and spirally wound to extend upward from the base 110 so as to allow the contact portion 130 to have vertical elasticity.

For example, elasticity, which allows an operational distance of the contact terminal 100 to increase 1.5 times longer than an original height thereof, may be provided.

To prevent the bridges 120 from interfering while the contact portion 130 vertically moves, reinforcing portions 121 and 122, which extend in a perpendicular direction to a direction in which the bridges 120 are wound, are formed at parts where the bridges 120 come into contact with the base 110 and the contact portion 130.

The reinforcing portions 121 and 122 allow the interval portions 112 between the bridges 120 and the base 110 and the bridges 120 and the contact portion 130 to have uniform widths throughout the bridges 120.

Also, the reinforcing portions 121 and 122 increase mechanical strength of parts where the bridges 120 are connected to the base 110 and the contact portion 130. Particularly, the reinforcing portion 122 allows the contact portion 130 to come into entire contact with the object when the contact portion 130 is completely pushed.

In the embodiment, the bridges 120 spirally extend clockwise when viewed from above but is not limited thereto and may extend counterclockwise.

A height of the contact terminal 100 may be determined by determining an angle at which the bridges 120 tilts upward and may be decreased by decreasing the angle of tilting upward.

Particularly, since the bridges 120 have a horizontal width much greater than a vertical thickness thereof, adequate elasticity may be provided even at a low height by applying high-strength metal.

The number of the bridges 120 is not particularly limited. Preferably, three bridges 120 may be formed while being spaced at a rotating angle of 120 degrees apart from one another. When the number of the bridges 120 is more than three, the width of the bridges 120 is decreased such that electrical resistance increases. When the number of the bridges 120 is less than three, the contact terminal 100 is structurally unsafe while being pressed and lacks stability against an external force.

The elastic contact terminal according to the embodiment of FIG. 1 may be used as a thermally conductive terminal or an electrical contact terminal which will be separately described in the following embodiment.

FIG. 2 is a perspective view of an elastic contact terminal according to another embodiment of the present invention.

According to the embodiment, an electroconductive elastic member 150 is attached to the other side of the contact portion 130.

Accordingly, while the base 110 is fixed to one object through soldering or welding, when another object pressurizes and pushes the contact portion 130, the elastic member 150 comes into contact with the one object.

As a result thereof, when the contact terminal 100 is vertically pushed, electrical resistance decreases and an inductance value decreases such that the contact terminal 100 may be used as an electrical contact terminal having high performance.

When the ribs 140 are present, electricity may be transmitted through the elastic member 150 only when a thickness of the elastic member 150 is greater than a height of the ribs 140.

The elastic member 150 may be an electroconductive silicone rubber or a metal spring and may be attached through self adhesion in the case of electroconductive rubber and may be attached through welding or soldering in the case of metal spring.

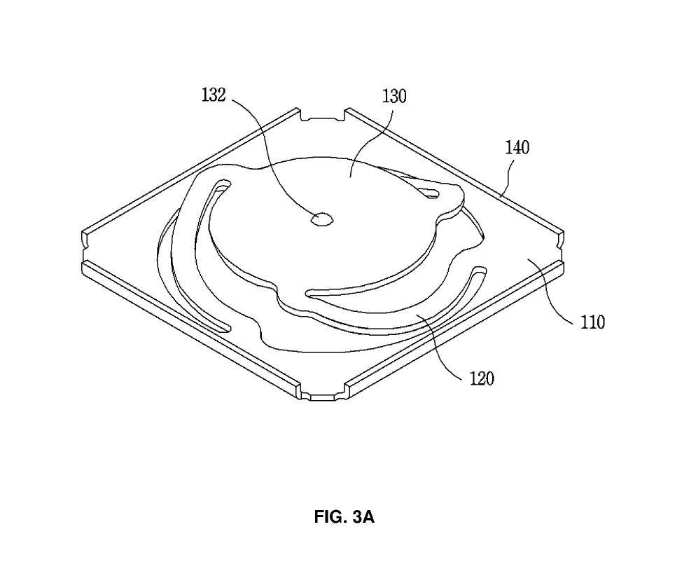

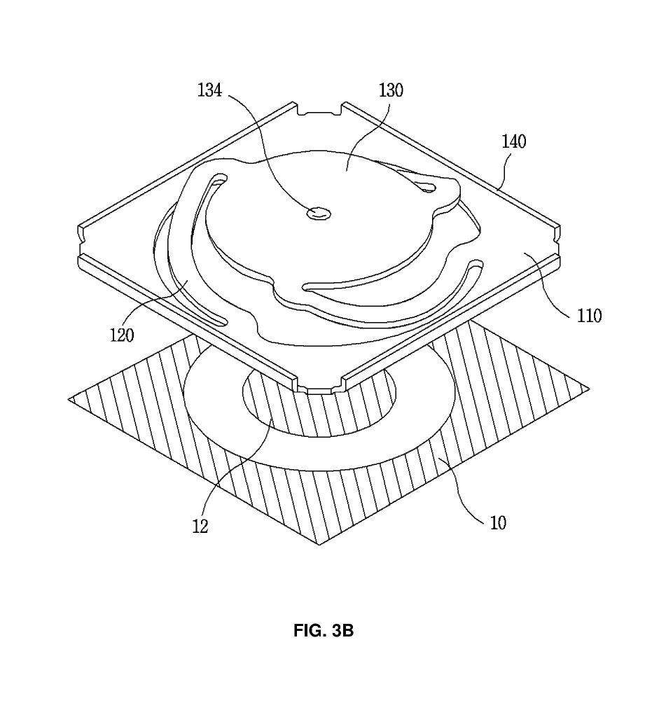

FIGS. 3A and 3B are perspective views of elastic contact terminals according to other embodiments of the present invention.

Referring to FIG. 3A, an embossing 132 protrudes upward from a center of a top surface of the contact portion 130 such that the contact portion 130 may undoubtedly come into physical contact with an opposite object.

Accordingly, the contact terminal 100 according to the embodiment may be used as a contact terminal in which the base 110 may be mounted on, for example, a conductive pattern of a printed circuit board through soldering and the contact portion 130 may come into contact with, for example, an antenna so as to transmit an electrical signal from the antenna to the circuit board.

Referring to FIG. 3B, with a structure in which the embossing 134 protrudes downward from a center of a bottom surface of the contact portion 130, the contact terminal 100 may be used as a switch.

In detail, in a circuit board where separate conductive patterns 10 and 12 are formed, when the base 110 of the contact terminal 100 is mounted on the conductive pattern 10, the contact portion 130 is located corresponding to the conductive pattern 12.

Accordingly, when the contact portion 130 is pushed to come into contact with the conductive pattern 12, an electrical path sequentially including the conductive pattern 10, the base 110, the bridge 120, the contact portion 130, and the conductive pattern 12 is formed.

Here, since the embossing 134, which protrudes from the center of the bottom surface of the contact portion 130, functions as an electrical contact point so as to allow the contact portion 130 and the conductive pattern 12 to undoubtedly come into physical and electrical contact with each other, the contact terminal 100 functions as an electrical switch which switches the conductive patterns 10 and 12 as a result.

When the elastic member 150 of FIG. 2 which has electrical conductivity is applied, the elastic member 150 functions as an excellent switch due to low electrical resistance and a low inductance value thereof.

In this structure, for example, a housing which accommodates the conductive patterns 10 and 12 and the contact terminal 100 therein is mechanically mounted on the circuit board and a pusher, which pressurizes the contact portion 130, is combined with the housing to be vertically movable so as to form a dome-shaped switch which may be used as an input device.

According to the embodiment, the same structure or a partial modification may operate as a contact terminal or a switch so as to be applied for many purposes.

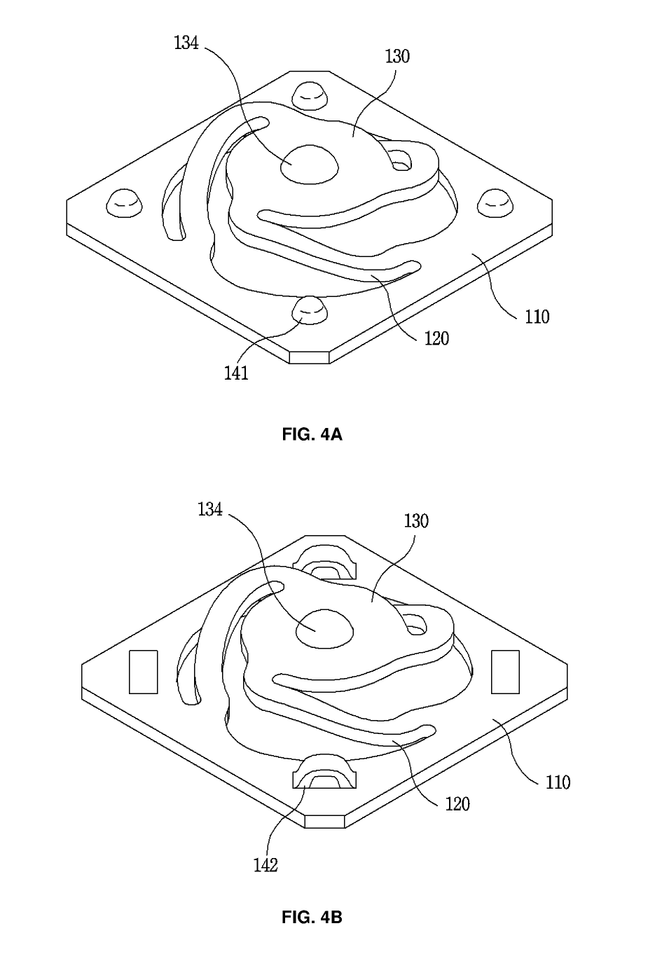

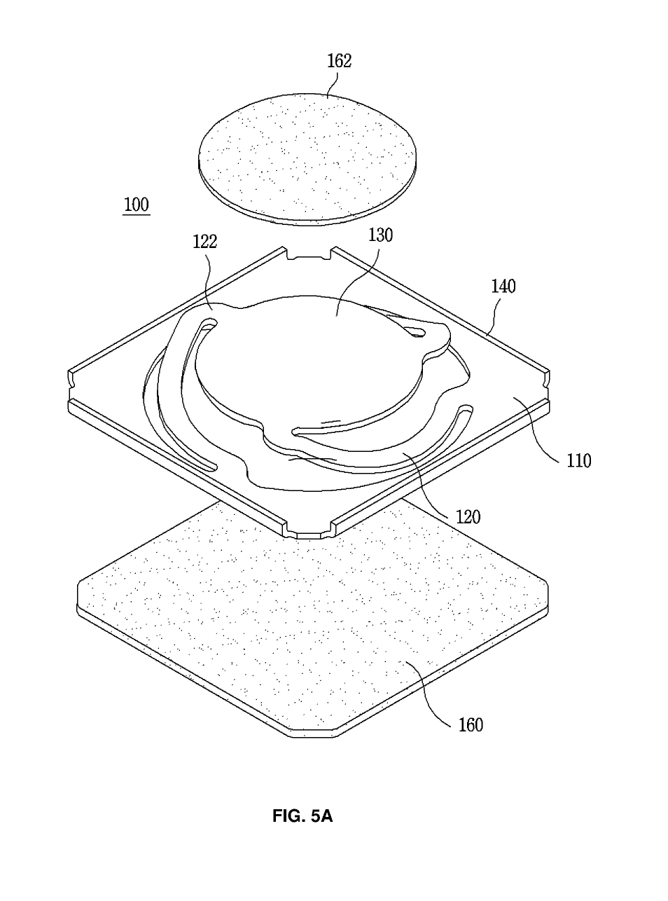

FIGS. 4A and 4B are perspective views of the elastic contact terminal according to another embodiment of the present invention.

Referring to FIG. 4A, embossings 141 protrude from a top surface of the base 110 corresponding to corners thereof. Referring to FIG. 4B, beadings 142 protrude from the top surface of the base 110 corresponding to the corners. These embossings 141 and the beadings 142 may function as the ribs 140 in the embodiment of FIG. 1.

As described above, since the base 110 has very small-sized widths and lengths and a particularly thin thickness of about 0.05 mm to 0.3 mm, it is not easy to form the ribs 140 as shown in FIG. 1. However, the embossings 141 and the beadings 142 may be relatively easily formed in comparison to the ribs 140 and may perform the same function.

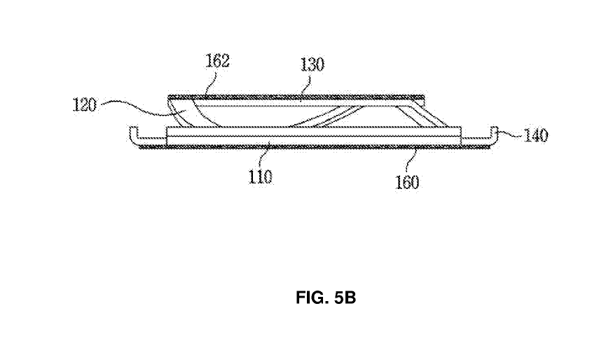

FIGS. 5A and 5B are perspective views of an elastic contact terminal according to another embodiment of the present invention.

The elastic contact terminal of FIG. 5 includes the same structure as that of FIG. 1 and has a difference therefrom in which thermally conductive members 160 and 162 are installed on the other side of the base 110 and the top surface of the contact portion 130.

The thermally conductive members 160 and 162 may include, for example, thermally conductive rubber, thermally conductive metal, thermally conductive ceramic, or thermally conductive carbon and may have elasticity and self adhesion.

Particularly, when the thermally conductive member 160 is installed on the other side of the base 110, the contact terminal 100 may be adhered to and arranged on release paper by using self adhesion of the thermally conductive member 160.

According to the embodiment, the contact terminal 100 may include a metal material having high heat conductivity such that heat applied to the base 110 or the contact portion 130 may be quickly transferred and diffused to the contact portion 130 or the base 110 on an opposite side through the bridges 120.

Also, a carbon layer having heat conductivity may be formed on an outer surface of the contact terminal 100 and may be formed by adhering, coating, or vapor-depositing, for example, carbon fibers, graphite, or graphene.

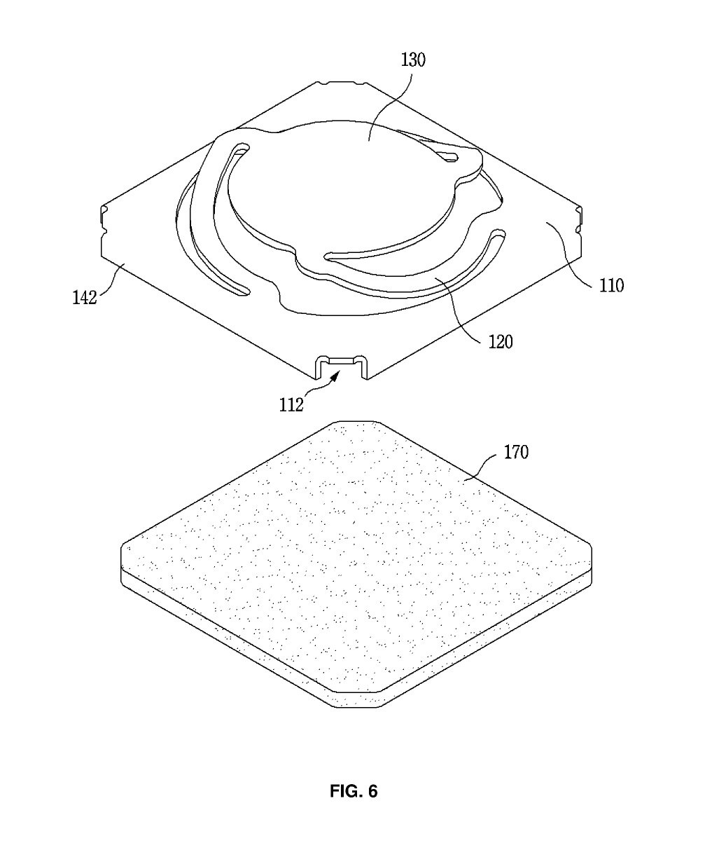

FIG. 6 is a perspective view of an elastic contact terminal according to another embodiment of the present invention.

According to the embodiment, the edges of the base 110 are bent downward and form ribs 140 so as to form an accommodation portion 143 below the base 110 and inside the ribs 140.

A thermally conductive member 170, which corresponds to a height of the ribs 140, in order words, has a thickness equal to or slightly protrude from the height of the ribs 140, is accommodated in and adhered to the accommodation portion 143. Particularly, a thickness of a thinnest part of the thermally conductive member 170 may be greater than the height of the ribs 140.

As described above, the thermally conductive member 170 may include, for example, thermally conductive rubber, thermally conductive metal, thermally conductive ceramic, or thermally conductive carbon and may have elasticity and self adhesion.

According to the structure, since heat may be transferred through the thermally conductive member 170 even at an empty central part of the base 110 while being in contact with the object, it is possible to quickly transfer heat.

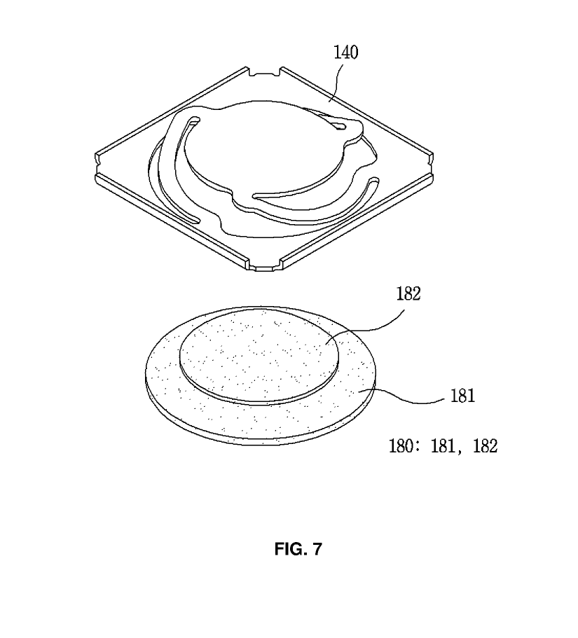

FIG. 7 is a perspective view of an elastic contact terminal according to another embodiment of the present invention.

When the contact terminal 100 is used as a thermally conductive member, heat is generally transferred through the bridges 120.

Here, since the bridge 120 has a horizontally smaller width, heat may not be effectively transferred through the bridges 120.

Accordingly, as shown in FIG. 2, the thermally conductive member 160 having elasticity may be installed or a thermally conductive member 180 as shown in FIG. 7 may be installed on the other side of the contact portion 130.

According to the embodiment, for example, while the base 110 is fixed to an object through soldering or welding, when a heating source comes into pressurized contact with the contact portion and transfers heat to the object, the contact portion is pressurized by the heating source and the thermally conductive member 160 or 180 comes into contact with the object.

In this state, since heat applied from the heating source to the contact portion 130 is transferred to the object through the thermally conductive member 160 or 180 in addition to the bridges 120, the heat may be more quickly transferred.

When the ribs 140, which bent upward from the edges of the base 110, are present, heat may be transferred through the thermally conductive member 160 only when a thickness of a thinnest part of the thermally conductive member 160 is thicker than a height of the ribs 140.

The thermally conductive member 180 is integrally formed by stacking a large-sized thermally conductive member 181 and a small-sized thermally conductive member 182. Here, the thermally conductive member 181 may cover a large space formed by the bridges 120 and the thermally conductive member 182 may cover a small space formed by the contact portion 130 so as to fill an empty space formed inside the base 110.

As described above, an elastic contact terminal, to which a thermally conductive member is applied, is installed between the heating source (heating element) and a metal case and comes into physically elastic contact with both the heating source and the metal case so as to transmit and emit (diffuse) heat from the heating source to the metal case.

Here, as much as a thermally conductive terminal is pressurized, heat resistance between the thermally conductive terminal and the metal case may be reduced so as to adequately transfer heat generated by the heating source to the metal case.

A surface of a semiconductor chip and a surface of the metal case are flush with each other so as to reduce heat resistance with the thermally conductive terminal. The metal case may include any one of magnesium, aluminum, copper, stainless steel and an alloy thereof. Also, the metal case may be a sheet-shaped metal plate, a box-shaped electromagnetic wave-shielding metal can, or a mechanical structure which forms a shape of an electronic device.

A base or a contact portion of a thermally conductive terminal may be attached to and come into contact with a metal case through a sticking agent or an adhesive having heat conductivity or through welding or soldering.

When a thermally conductive member is installed on a top surface or a bottom surface of a contact portion or a bottom surface of a base, the thermally conductive member of the base or the contact portion may be attached to and come into contact with a metal case through a sticking agent or an adhesive having heat conductivity or through welding or soldering and thermally conductive performance and heat diffusion performance of a thermally conductive terminal may be increased by the thermally conductive member.

Although the embodiments of the present invention have been described above, a variety of changes and modifications may be made by one of ordinary skill in the art without departing from the essential features of the present invention. Accordingly, the embodiments disclosed herein are not intended to limit but explain the technical concept of the present invention, and the scope of the technical concept of the present invention should not be limited by the above embodiments. The scope of the present invention should be interpreted by the following claims and all technical concepts within the equivalent scope thereof should be interpreted as being included in the scope of the present invention.

What is claimed is:

1. An elastic contact terminal, which is formed of a single body having a metal material, the elastic contact terminal comprising:
a base;
a plurality of bridges which have one end connected to the base, are spirally wound, extend in an upward inclination, and have vertical elasticity; and
a contact portion to which the other end of each of the bridges is connected,
wherein each of the bridges extends between the contact portion and the base while maintaining a certain interval therebetween, and
wherein the bridges have a horizontal width greater than a vertical thickness.

2. The elastic contact terminal of claim 1, wherein edges of the base are bent upward or downward and form ribs.

3. The elastic contact terminal of claim 2, wherein an accommodation portion is formed inside the ribs, which are bent downward, such that a thermally conductive member is accommodated in the accommodation portion.

4. The elastic contact terminal of claim 1, wherein a reinforcing portion, which extends toward a perpendicular line with respect to the winding direction, is formed a part of the bridge which is connected to the base and the contact portion, and
wherein the certain interval may be maintained throughout the bridge due to the reinforcing portion.

5. The elastic contact terminal of claim 1, wherein the thermally conductive member is installed on a top surface or a bottom surface of the contact portion or a bottom surface of the base.

6. The elastic contact terminal of claim 5, wherein the thermally conductive member comprises any one of thermally conductive rubber, thermally conductive metal, thermally conductive ceramic, and thermally conductive carbon.

7. The elastic contact terminal of claim 5, wherein the thermally conductive member installed on the bottom surface of the contact portion is formed by stacking a large-sized first thermally conductive member and a small-sized second thermally conductive member, and
wherein the first thermally conductive member covers a space formed in the base by the bridges and the second thermally conductive member covers a space formed by the contact portion so as to fill an empty space formed inside the base.

8. The elastic contact terminal of claim 5, wherein edges of the base are bent upward and form ribs, and
wherein a thickness of a thinnest part of the thermally conductive member installed on the other side of the contact portion is greater than a height of the ribs.

9. The elastic contact terminal of claim 5, wherein the thermally conductive member has elasticity and self adhesion.

10. The elastic contact terminal of claim 1, wherein one or more embossings protrude upward from a top surface of the contact portion or protrude downward from a bottom surface of the contact portion.

11. The elastic contact terminal of claim 1, wherein an embossing protrudes downward from a bottom surface of the contact portion and operates as an electrical contact point when the contact portion is pressurized downward.

12. The elastic contact terminal of claim 1, wherein an embossing protrudes downward from a bottom surface of the contact portion, and
wherein the base is electrically connected to a first conductive pattern and the embossing is, selectively, electrically connected to a second conductive pattern by vertical movement of the contact portion and performs switching between the first and second conductive patterns.

13. The elastic contact terminal of claim 1, wherein an embossing or a beading protrudes upward from a top surface of the base corresponding to each corner thereof.

14. The elastic contact terminal of claim 1, wherein the contact terminal comprises a plating layer formed at an outermost part thereof by consecutively plating nickel and gold or plating tin or silver so as to have high environmental resistance and to be reflow-soldered using a solder cream.

15. The elastic contact terminal of claim 1, wherein a carbon layer having high heat conductivity is formed on an outer surface of the contact terminal.

16. The elastic contact terminal of claim 15, wherein the carbon layer is formed by adhering, coating, or vapor-deposing carbon fibers, graphite, or graphene.

17. A switch device comprising the contact terminal of claim 1, wherein the base is electrically connected to a first conductive pattern of a circuit board and the contact portion is disposed corresponding to a second conductive pattern electrically separated from the first conductive pattern, the switch device comprising:
a housing which accommodates the contact portion and the first and second conductive patterns therein; and
a pusher combined with the housing to be vertically movable,
wherein the contact portion is, selectively, electrically connected to the second conductive pattern due to vertical movement of the pusher and performs switching between the first and second conductive patterns.

18. An electronic device comprising the contact terminal of claim 1 and interposed between opposite objects, wherein one of the base and the contact portion is mounted on one of the objects through soldering, and
wherein the other of the base and the contact portion comes into physically elastic contact with the other of the objects.

19. An electronic device comprising the contact terminal of claim 1, wherein any one of the base and the contact portion is attached to and comes into contact with a metal case located on a heating element mounted on a circuit board through a sticking agent or an adhesive having heat conductivity or through welding or soldering and the other comes into physically elastic contact with a surface of the heating element.

20. An electronic device comprising the contact terminal of claim 1, wherein a thermally conductive member is installed on a top surface or a bottom surface of the contact portion or a bottom surface of the base, and
wherein any one of the thermally conductive member of the base and the thermally conductive member of the contact portion comes into physical contact with a heating element mounted on a circuit board and the other comes into physically elastic contact with a metal case located on the heating element.

21. An electronic device comprising the contact terminal of claim 1, wherein a thermally conductive member is installed on a top surface or a bottom surface of the contact portion or a bottom surface of the base, and
wherein any one of the thermally conductive member of the base or the thermally conductive member of the contact portion is attached to and comes into contact with a metal case located on a heating element mounted on a circuit board through a sticking agent or an adhesive having heat conductivity or through welding or soldering and the other comes into physically elastic contact with a surface of the heating element.
